(19) United States
(12) Patent Application Publication
(10) Pub. No.: US 2002/0030272 A1
(43) Pub. Date: Mar. 14, 2002

(54) SEMICONDUCTOR APPARATUS SUBSTRATE, SEMICONDUCTOR APPARATUS, AND METHOD OF MANUFACTURING THEREOF AND ELECTRONIC APPARATUS

(76) Inventor: AKIHIRO MURATA, YAMANASHI-KEN (JP)

Correspondence Address: OLIFF & BERRIDGE, P O BOX 19928, ALEXANDRIA, VA, 22320

(21) Appl. No.: 09/245,288

(22) Filed: Feb. 5, 1999

(30) Foreign Application Priority Data
Feb. 17, 1998 (JP) 10-51359

(51) Int. Cl. H01L 23/04; H01L 23/48; H01L 23/52; H01L 29/40

(52) U.S. Cl. 257/734

(57) ABSTRACT

A semiconductor apparatus and method of manufacturing and an electronic apparatus are provided that achieve excellent productivity and substantially reduced manufacturing costs. The semiconductor apparatus may include a substrate main body having a mounting surface for mounting the semiconductor device, a plurality of leads formed on the mounting surface and a plurality of conduction sections each defining at least a part of an external terminal. The conduction sections may be electrically connected to each of the leads.

### BACKGROUND OF THE INVENTION

1. Field of Invention

The present invention relates to a substrate for a semiconductor apparatus, a semiconductor apparatus and a method for manufacturing thereof, and an electronic apparatus.

2. Description of Related Art

A bare-chip mounting method may be used to further miniaturize semiconductor apparatuses. However, quality control and handling of semiconductor apparatuses made by such a method are difficult and thus semiconductor apparatuses are provided in packages in order to avoid such difficulties. One example of such packages is a BGA (Ball Grid Array) type package in which a semiconductor chip is connected to a substrate having wiring patterns, and external terminals are formed on the wiring patterns. Japanese Laid-Open Patent Application HEI 8-107161, the subject matter of which is incorporated herein by reference, describes another type of package for a semiconductor apparatus using a substrate in which external terminals are formed on a peripheral edge area of the substrate.

In these types of semiconductor apparatuses, when common substrates having a uniform size are used to reduce the manufacturing costs, the size of semiconductor apparatuses is fixed without regard to the size of semiconductor chips. Accordingly, even when small semiconductor chips are used, the resultant semiconductor apparatuses are relatively large. In order to avoid this, substrates having different sized substrates are manufactured depending on the size of the semiconductor chips. As a result, the demand for increased productivity and reduced costs cannot be met.

Also, since the bonding work for semiconductor chips is time consuming, the demand for increased productivity and reduced costs cannot be met.

### SUMMARY OF THE INVENTION

The present invention may solve the above described problems. It is an object of the present invention to provide a semiconductor apparatus substrate, a semiconductor apparatus and a method for manufacturing thereof, and an electronic apparatus that achieves excellent productivity and reduces manufacturing costs.

A semiconductor apparatus substrate in accordance with the present invention may be adapted to mount a semiconductor device thereon to form a semiconductor apparatus. The substrate may include a substrate main body having a mounting surface for mounting the semiconductor device, a plurality of leads formed on the mounting surface and a plurality of conduction sections each defining at least a part of an external terminal. The conduction sections may be electrically connected to each of the leads.

A group of conduction sections may be electrically connected to each of the leads. Therefore, when the semiconductor apparatus substrate is cut such that at least one of the conduction sections remains for each of the leads, the remaining conduction section is used as an external electrode. As a result, when a small size semiconductor device is mounted, the semiconductor apparatus substrate can be cut so that the size of the semiconductor apparatus becomes smaller.

The substrate main body may include a plurality of through-holes for each of the leads. The through-holes may have internal surfaces that are conductive and connected to each of the respective leads. Predetermined ones of the internal surfaces may define the conduction sections as the substrate main body is cut along the corresponding ones of the through-holes.

As a result, the internal surfaces of the through-holes that become the conduction sections as they are cut may be located at side end surfaces of the substrate main body. Therefore, the internal surfaces may be used as external terminals.

The substrate main body may define a central area and have one through-hole at the side of the central area for each of the leads. Conduction sections may be formed on a surface opposite of the mounting surface of the semiconductor device and may be electrically connected to the corresponding lead through the through-hole.

The through-hole for electrically connecting the leads and the conduction sections may be formed on the side of the central area of the substrate main body. Therefore, if outer ones of the conduction sections are cut, conduction between inner ones of the conduction sections and the leads may be maintained. As a result, the manufactured semiconductor apparatuses can be miniaturized.

The substrate main body may have a plurality of through-holes for each of the leads. The conduction sections may be formed on a surface opposite of the mounting surface of the semiconductor device and be electrically connected to each corresponding lead through a predetermined one of the through-holes.

By this structure, the conduction sections may be individually connected to the lead through the through-holes. As a result, if the outer conduction section is cut, the inner conduction section and the lead can maintain their conductive state. As a result, the manufactured semiconductor apparatuses can be miniaturized.

The leads may radially extend from a peripheral area toward the central area of the substrate main body. As a result, the leads may be radially disposed, and therefore many leads can be disposed with high density.

A semiconductor apparatus in accordance with the present invention may also include: a semiconductor device having a plurality of electrodes, a substrate main body, a plurality of leads formed on the substrate main body and a plurality of conduction sections formed on the substrate main body and defining at least part of an external terminal. The conduction sections may be electrically connected to each of the leads, and one of the group of conduction sections may define the external terminal.

The present invention may provide a semiconductor apparatus manufactured by utilizing the semiconductor apparatus substrate described above.

A method of manufacturing a semiconductor apparatus in accordance with the present invention may include: a step of preparing a substrate including a plurality of leads and a plurality of conduction sections defining at least a part of external terminals. Each of the leads may be electrically connected to the plurality of conduction sections. The method may further include a step of mounting a semiconductor device on the substrate and a step of electrically connecting electrodes of the semiconductor device to the leads. The method may also include a step of cutting the substrate while leaving uncut at least one of the conduction sections connected to the corresponding one of the leads.

The present invention may thus provide a method for manufacturing a semiconductor apparatus using the above described semiconductor apparatus substrate.

In the above method, the semiconductor device has a surface having the electrodes. The surface of the semiconductor device may be attached to the substrate and the electrodes of the semiconductor device may be directly connected to the lead.

As a result, when semiconductor devices of different sizes are mounted, only connecting positions of the leads and the electrodes change so that substrates having a common size can be used regardless of the size of the semiconductor devices.

The method may further include a step of providing a conductive connection member at the electrodes of the semiconductor device. The step of electrically connecting the electrodes and the leads may include a step of providing insulation adhesive members between the electrodes and the leads and a step of pushing the semiconductor device against the substrate and at the same time heating at a temperature higher than a melting temperature of the insulation adhesive member and lower than a melting temperature of the conducting connection member. A step of melting the conductive connection member may also be included.

As a result, the semiconductor device and the substrate may be readily connected to one another. In this method, the substrate may be provided with a through-hole for each of the leads. The through-hole may communicate with a through-hole defined in each of the leads on the side of a central area of the substrate. The conduction sections may be electrically connected to each corresponding one of the leads through the through-hole of the substrate. The substrate may be cut after the step of electrically connecting the electrodes and the leads.

In accordance with the above structure, the through-holes for electrically connecting the leads and the conduction sections may be formed on the side of the central area of the substrate main body. Therefore, if outer ones of the conduction sections are cut, conduction between inner ones of the conduction sections and the leads is maintained. As a result, the manufactured semiconductor apparatus can be miniaturized.

In accordance with the above described manufacturing method, the substrate may be provided with a plurality of through-holes for each one of the leads. Each of the through-holes may communicate with a through-hole passing through each of the leads. The conduction sections may be electrically connected to corresponding leads through predetermined through-holes. The substrate may be cut after the step of electrically connecting the electrodes and the leads.

As a result, the conduction sections may be individually connected to the lead through the through-holes. As a result, even when the outer conduction section is cut, the inner conduction section and the lead can maintain their conductive state. As a result, the thus manufactured semiconductor apparatuses can be miniaturized

The substrate may be provided with a plurality of through-holes for each of the leads. Internal surfaces of the through-holes may be made to be conductive and connected to corresponding leads. The substrate may be cut at locations that pass predetermined ones of the through-holes to define the conduction sections.

As a result, the internal surfaces of the through-holes may define the conduction sections and can be used as external terminals by simply cutting the substrate at locations that pass the through-holes. Also, the substrate may be cut along predetermined ones of the plurality of through-holes depending on the size of a semiconductor device to provide a smallest effective area so that the size of a resultant semiconductor apparatus can be minimized.

An electronic apparatus in accordance with the present invention may have a circuit substrate mounted with the semiconductor apparatus described above.

A semiconductor apparatus 10 may be formed from a substrate 12 and a semiconductor device 14 mounted thereon. The substrate 12 may include a substrate main body 18, a plurality of leads 20 formed on a mounting surface of the substrate 12 on which the semiconductor device 14 is mounted, and conduction sections 26 electrically connected to each of the leads to define at least part of external terminals. A relatively large substrate is cut to obtain the substrate 12, and a plurality of conduction sections are formed for each of the leads formed on the large substrate.

Other objects, advantages and salient features of the invention will become apparent from the detailed description taken in conjunction with the annexed drawings, which disclose preferred embodiments of the invention.

### BRIEF DESCRIPTION OF THE DRAWINGS

The invention will be described with reference to the following drawings in which like reference numerals refer to like elements and wherein:

FIG. 1 shows a semiconductor apparatus in accordance with a first embodiment of the present invention;

FIG. 2 shows a substrate used for a semiconductor apparatus in accordance with the first embodiment;

FIGS. 3(A) to 3(C) illustrate a method of manufacturing a semiconductor apparatus in accordance with the first embodiment;

FIGS. 4(A) and 4(B) show a substrate for a semiconductor apparatus in accordance with a second embodiment of the present invention;

FIGS. 5(A) and 5(B) show substrates obtained by cutting the substrate of the second embodiment;

FIGS. 6(A) and 6(B) show a substrate for a semiconductor apparatus in accordance with a third embodiment of the present invention;

FIGS. 7(A) to 7(C) illustrate a method of manufacturing a semiconductor apparatus in accordance with a fourth embodiment of the present invention;

FIG. 8 shows a circuit substrate having a semiconductor apparatus mounted thereon in accordance with the present invention; and

FIG. 9 shows an electronic apparatus in accordance with the present invention.

### DETAILED DESCRIPTION OF PREFERRED EMBODIMENTS

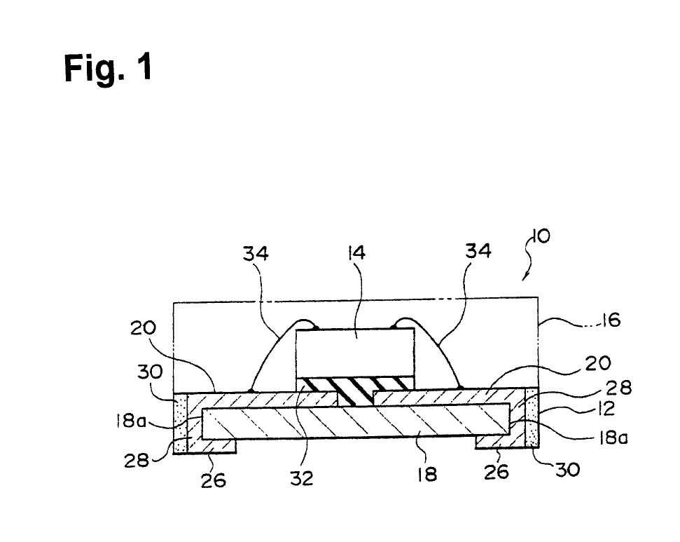

Embodiments of the present invention will be described below with reference to the accompanying drawings. FIG. 1 shows a semiconductor apparatus in accordance with a first embodiment of the present invention. A semiconductor apparatus 10 may include a semiconductor apparatus substrate (also called hereafter substrate) 12 and a semiconductor device (semiconductor chip=IC chip=bare chip) 14 that are sealed by molding resin 16.

The substrate for the semiconductor apparatus 12 includes a rectangular substrate main body 18, a plurality of leads 20 formed on one surface of the substrate main body 18, and a plurality of conduction sections 26 formed on another surface which is opposite to the surface of the substrate main body 18. For example, the substrate 12 may be formed from: (1) a metal substrate having a core defined by the substrate main body 18 that is relatively hard and has a relatively high coefficient of thermal conductivity, such as, for example, copper, aluminum, and the like, (2) a glass-epoxy substrate (i.e., printed circuit board), (3) a lead frame made of alloy, copper or the like, and (4) a flexible substrate that is relatively soft and flexible, such as, for example, polyimide substrate or the like. The same substrate may be applicable to other embodiments.

A metal substrate may be used in a preferred embodiment of the present invention. A metal substrate may be manufactured by the following method. First, insulation films of resin, glass epoxy or the like are provided on both surfaces of a base member of copper, aluminum or the like. Conductive wires are formed on both insulation films. Apertures, which are formed in the base member in advance, are filled with the insulation film, and through-holes of smaller diameter are formed in the center of the apertures. Conductive members are provided in the through-holes. The wiring patterns on the front and the rear surfaces are electrically connected to one another through the conductive members. As a result, this method provides a metal substrate with both of its surfaces electrically connected.

The leads 20 extend from a pair of parallel side edges of the substrate main body 18 toward areas adjacent to the central area of the substrate main body 18. One pair of the leads 20 extends from the side edges toward the opposite edges such that a gap is formed between the pair of the leads 20 adjacent the central area.

Semi-circular cuts 18a are formed in the side edges of the substrate main body 18. Conductive layers 28 are formed on the surfaces of the cuts 18a, and conduction sections 26 are provided at locations corresponding to the respective conductive layers 28. The conduction sections 26 and the conductive layers 28 are continuously formed so that they can be generally defined as conduction sections. The leads 20 are electrically connected to the conductive layers 28 and the conduction sections 26, respectively. Solder sections 30 are provided on the conductive layers 28. The conductive layers 28, the conduction sections 26 and the solder sections 30 form external terminals. However, the solder sections 30 can be omitted if provided on the side of a mounting substrate.

The semiconductor device 14 is attached through an insulation sheet 32 to a surface of the substrate main body 18 on which the leads 20 are provided. In another embodiment, insulation adhesive may be used instead of the insulation sheet 32.

The semiconductor device 14 is positioned above portions of the leads 20 and 22. In other words, portions of the leads 20 are located below the semiconductor device 14, and the remaining portions are located outside the semiconductor device 14. Because the semiconductor device 14 is mounted on the leads 20, the insulation sheet 32 is disposed between them to provide electrical insulation.

The semiconductor device 14 is electrically connected through wires 34 to the leads 20 at areas outside the semiconductor device 14. More specifically, the semiconductor device 14 defines a mounting surface to be mounted on the substrate main body 18 and has electrodes (not shown) provided on its surface opposite of the mounting surface. The wires 34 connect the electrodes and the leads 20.

The molding resin 16 covers the semiconductor device 14, the wires 34 and the mounting surface of the substrate main body 18 that mounts the semiconductor device 14.

In accordance with the present invention, the semiconductor device 14 is placed on the leads 20 and 22, and is connected to the leads 20 in areas outside the semiconductor device 14. As a result, portions of the leads 20 that are located under the semiconductor device 14 and portions of the leads 20 that are located outside the semiconductor device 14 may be at any length ratio. Accordingly, they do not present any particular problems unless they interfere with the wire bonding by the wires 34. Therefore, a semiconductor device having a different size than the semiconductor device 14 can be used. In this case, the length of the leads 20 located under the semiconductor device becomes different.

As a result, the substrate 12 can accommodate and therefore can be commonly used for semiconductor devices of various sizes. This reduces the costs.

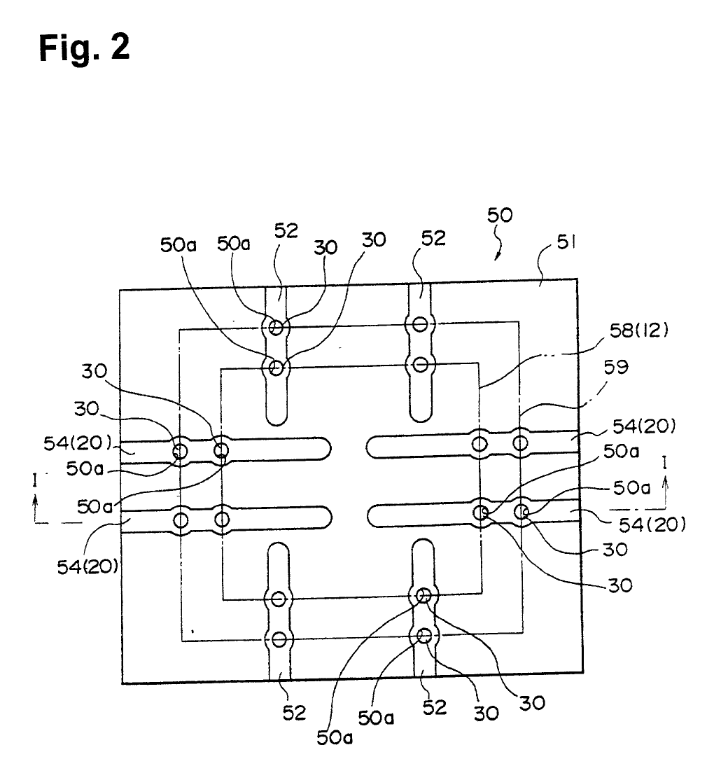

Furthermore, the size of the substrate can be changed. The substrate 12 is formed from a substrate 50 shown in FIG. 2 by cutting along a contour line 58. FIG. 1 shows a cross-sectional view of the substrate 12 taken along lines I-I of FIG. 2.

The substrate 50 has a plurality of leads 52 and 54 disposed on one surface of a substrate main body 51. The leads 52 and 54 extend from the periphery toward the central area of the substrate main body 51. As the leads 54 are cut, they define the leads 20 shown in FIG. 1. Through-holes 50a are formed in the substrate 50 and solder 30 is provided in the through-holes 50a. The leads 52 and 54 have wider areas in which the through-holes 50a are formed in the wider areas.

The through-holes 50a are located on contour lines 58, 59 of different sizes. When they are cut along the contour line 58, the substrate 12 shown in FIG. 1 is obtained.

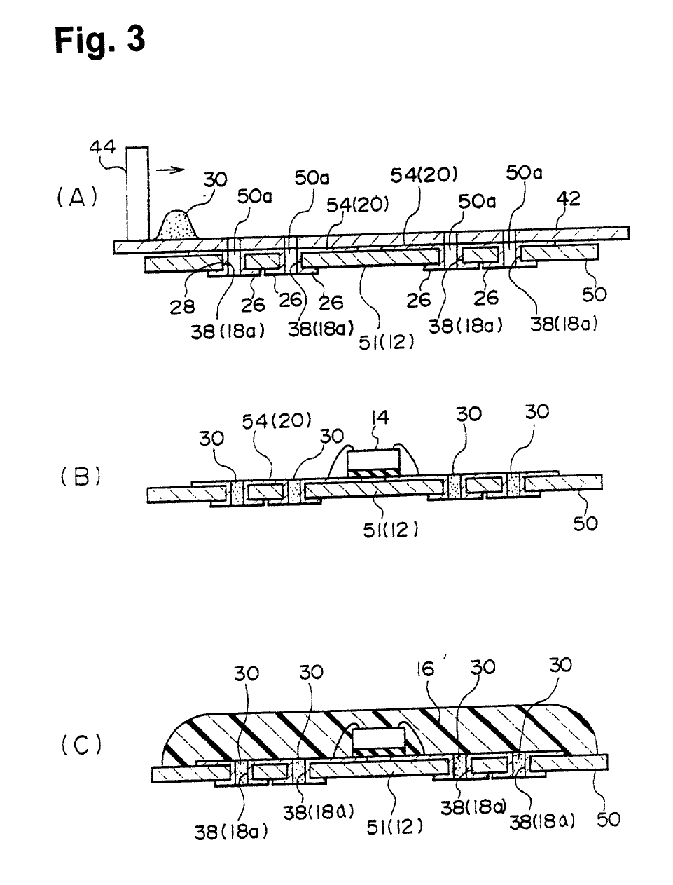

Also, conduction sections 26 are formed on another surface of the substrate 50 opposite of the surface on which the leads 52, 54 are formed as shown in FIG. 3(A). As the conduction sections 26 are cut, they define the conduction sections 26 of the substrate 12 shown in FIG. 1.

In accordance with the present embodiment, the substrate 50 may be cut at a plurality of different cutting locations. For example, when a semiconductor device to be mounted is smaller in size than the rectangular contour 58, the substrate 50 is cut along the contour 58. This provides a relatively small semiconductor apparatus. When a semiconductor device to be mounted is larger in size than the rectangular contour 58, the substrate 50 is cut along the contour 59 to accommodate the semiconductor device of such size.

Accordingly, the size of the substrate 50 can be changed according to the size of semiconductor devices. As a result, the substrate 50 can be adapted for common use, and semiconductor apparatuses of different sizes can be obtained from the substrate 50. In other words, when a small size semiconductor device is mounted, the substrate 50 is cut into a smaller size to provide a semiconductor apparatus having a smaller size.

The solder 30 may also be omitted. In this case, when the substrate 50 is cut along the contour 59, the through-holes 50a located along the contour 58 remain uncut. Alternatively, when the substrate 50 is not cut at all, all of the through-holes 50a remain. In this case, the through-holes 50a remain in a semiconductor apparatus as a final product, and the through-holes 50a function as air ventilation holes. As a result, when the semiconductor apparatus is heated during a reflow process or the like, air or water vapor expanded within the semiconductor apparatus can be ventilated.

FIGS. 3(A) to 3(C) illustrate a method of manufacturing a semiconductor apparatus in accordance with the present invention. A stencil 42 may be placed on a substrate 50 as shown in FIG. 3(A).

A plurality of through-holes 38 may be formed in a substrate main body 51. The through-holes 38 defme cut sections 18a shown in FIG. 1 as the through-holes 38 are cut. The leads 54 and the conduction section 26 are formed around each of the through-holes 38. The same structure is provided to the leads 52 shown in FIG. 2, although not shown in FIG. 3(A). Conduction layers 28 are formed on internal surfaces of the through-holes 38. The surfaces of the conduction layers 28 surround the respective through-holes 50a.

Then, solder 30 in the form of paste is placed on the stencil 42 and a squeegee 44 is moved to fill the solder 30 in the through-holes 50a.

As shown in FIG. 3(B), a semiconductor device 14 is mounted on and wirebonded to the substrate 50 for electrical connection.

Then, as shown in FIG. 3(C), a resin-sealing step is performed using molding resin 16. Then, when the substrate 50 is cut along the through-holes 38 (i.e., the through-holes 50a), a plurality of semiconductor apparatuses 10 shown in FIG. 1 are manufactured.

The above described manufacturing method is described in Japanese Laid-Open Patent Application HEI 8-107161, the subject matter of which is incorporated herein by reference. Alternatively, the substrate 12 may be cut into individual pieces in advance, and then, semiconductor devices 14 may be attached to the respective individual pieces.

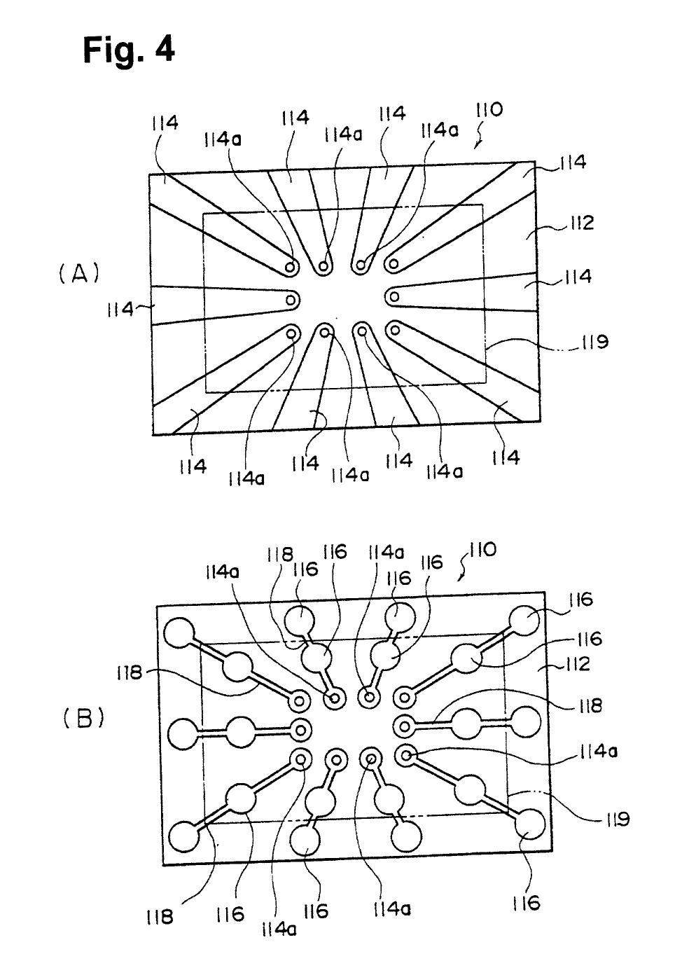

FIGS. 4(A) and 4(B) show a substrate for a semiconductor in accordance with a second embodiment of the present invention. FIGS. 4(A) and 4(B) show one surface and the other surface of the substrate, respectively.

As shown in FIG. 4(A), leads 114 are formed on one surface of a substrate main body 112 of a substrate 110 such that the leads 114 radially extend from the periphery toward the central area of the substrate 110. A semiconductor device 119 is mounted on the leads 114. Electrodes (not shown) of the semiconductor device 119 and the leads 114 are bonded together by wire-bonding or a facedown bonding method.

In this embodiment, the semiconductor device 119 is placed on the leads 114. As a result, the leads 114 can be used as they are if the size and/or the configuration of the semiconductor device 119 is changed.

A through-hole 114a is formed in each of the leads 114 in the central area of the substrate 110. The through-holes 114a are defined by conduction layers (not shown) that electrically connect both of the surfaces of the substrate main body 112. In this respect, the through-holes 114a are similar to the through-holes 50a shown in FIG. 2.

As shown in FIG. 4(B), a plurality of conduction sections 116 are formed on the other surface of the substrate main body 112. More specifically, wiring sections 118 are formed such that the conduction layers (not shown) defining the through-holes 114a conductively connect to the wiring section 118, and a plurality of conduction sections 116 are formed on the respective wiring sections 118. Accordingly, a plurality of conduction sections 116 conductively connect to each of the leads 114. Moreover, a plurality of conduction sections 116 and each of the leads 114 are electrically connected to one another through the conduction layers (not shown) on the side of the central area of the substrate main body 112.

Solder balls are provided on the conduction sections 116 to define external terminals. In accordance with the present embodiment, since a plurality of conduction sections 116 are provided for each one of the leads 114, any one of the conduction sections 116 can be selected to form external terminals. As shown in FIG. 4(B), when the external contour of the semiconductor device 119 is within predetermined ones of the conduction sections 116 of the leads 114, the substrate main body 112 is cut within the predetermined ones of the conduction sections 116. The leads 114 and the conduction sections 116 may be electrically connected to one another on the side of the center area of the substrate main body 112. Therefore, the substrate main body 112 can be cut anywhere but outside of the central area. The conduction between the leads 114 and the conduction sections 116 is not cut. As a result, depending on the size and shape of semiconductor devices, the size of semiconductor apparatuses to be manufactured can be reduced as small as possible.

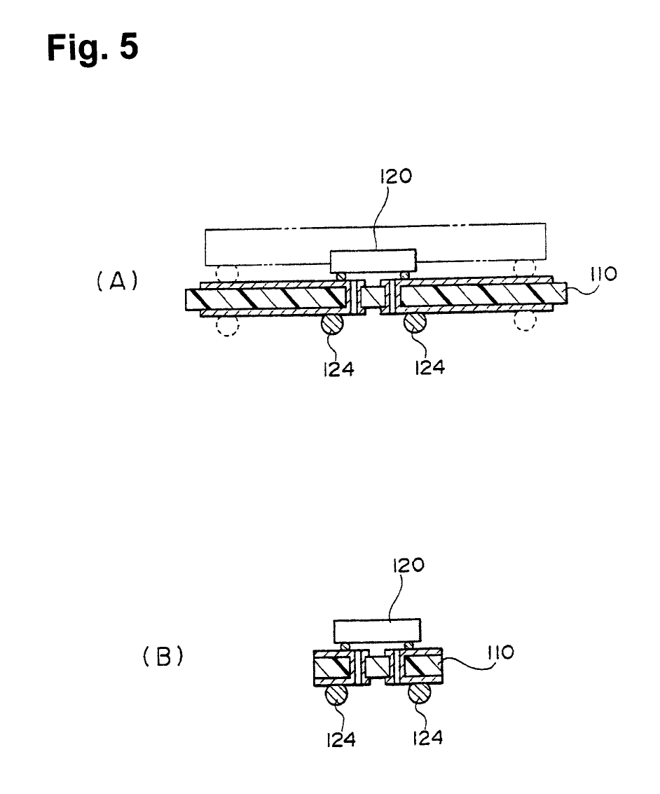

For example, as shown in FIG. 5(A), a semiconductor device 120 of a smaller size or a larger size can be attached to the substrate 110. When the smaller semiconductor device 120 is attached to the substrate 110, the substrate 110 is cut at locations outside solder balls 124 as shown in FIG. 5(B) to provide a semiconductor apparatus of a smaller size.

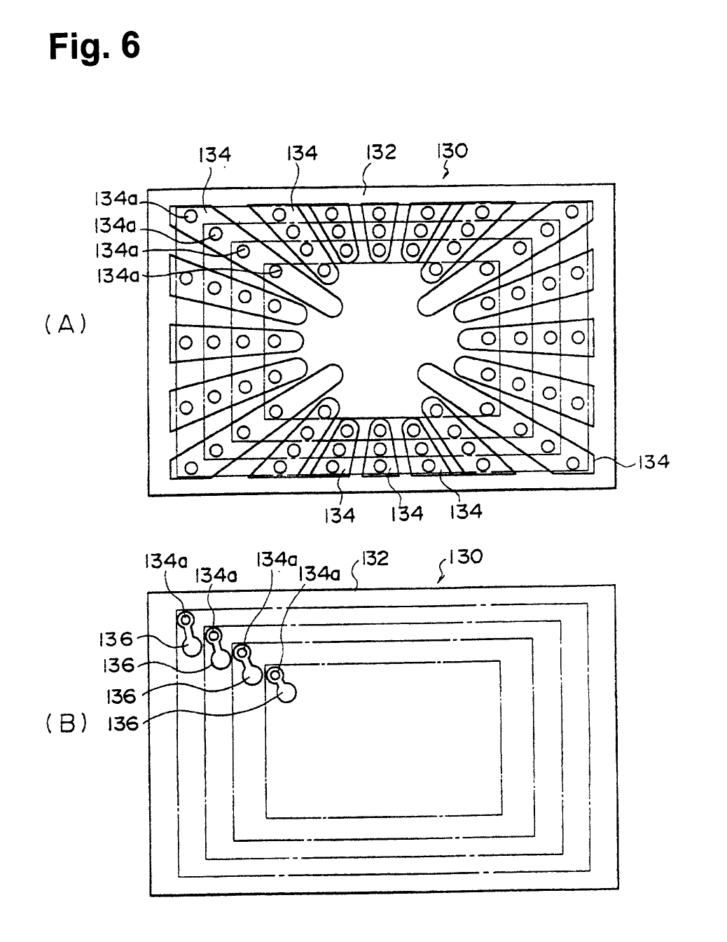

FIGS. 6(A) and 6(B) show a substrate for a semiconductor apparatus in accordance with a third embodiment of the present invention. FIGS. 6(A) and 6(B) show one surface and the other surface of the substrate, respectively. FIG. 6(A) shows a substrate 130 having a substrate main body 132 and leads 134 formed on the substrate main body 132. A semiconductor device (not shown) is placed on at least a portion of at least one of the leads 134 on the substrate main body 132 of the substrate 130. Electrodes of the semiconductor device are electrically connected to the leads 134.

In accordance with this embodiment, a plurality of conduction sections 136 shown in FIG. 6(B) are formed for each of the leads 134 shown in FIG. 6(A). FIG. 6(B) shows only part of the conduction sections 136 while a description of remaining parts are omitted.

A plurality of through-holes are formed in each of the leads 134. Through-holes (not shown) are formed in the substrate main body 132, and a conduction layer is formed on each of the through-holes. Each of the through-holes is formed on a surface of the conduction layer of each of the through-holes of the substrate main body 132. The leads 134 formed on one surface of the substrate main body 132 are electrically connected to the conduction sections 136 formed on the other surface of the substrate main body 132 through the conduction layers that form the throughholes 134a. The through-hole 134a is formed for each of the conduction sections 136.

Because the plurality of conduction sections 136 are provided for each of the leads 134, specified ones of the conduction sections 136 are selected and the substrate main body 132 is cut accordingly. For example, any one of four rectangular contours shown in dot-and-dash lines in FIGS. 6(A) and 6(B) is selected and the substrate 132 is cut along the selected contour.

In accordance with this embodiment, the cutting position may be changed depending on the size of semiconductor devices to be mounted. As a result, a semiconductor apparatus of a relatively small size may be obtained for a semiconductor device of a relatively small size. Further, a semiconductor apparatus of a relatively large size may be obtained for a semiconductor device of a relatively large size. Also, if a plurality of the conduction sections 136 remain for each of the leads 134 when the substrate 130 is cut, any one of the conduction sections 136 may be selected to form solder balls so that the location of solder balls is changed.

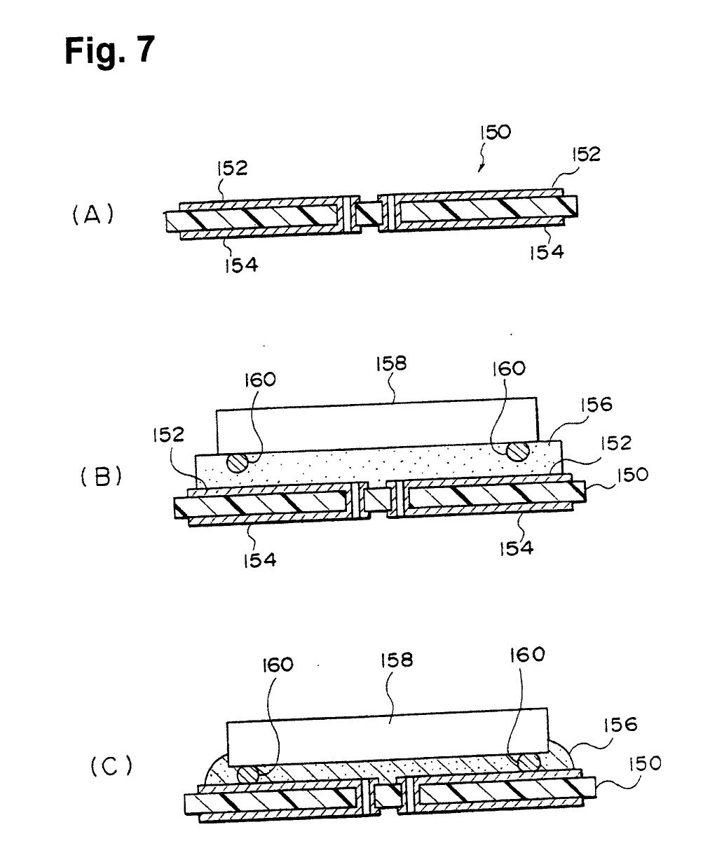

FIGS. 7(A) to 7(C) illustrate a method of manufacturing a semiconductor apparatus in accordance with a fourth embodiment of the present invention.

As shown in FIG. 7(A), a substrate 150 for a semiconductor apparatus is initially prepared. The substrate 150 is any one of the substrates made in accordance with the embodiments described above, and has a plurality of leads 152 and a plurality of conduction sections 154.

As shown in FIG. 7(B), insulation adhesive 156 may be provided on the leads 152 of the substrate 150. The insulation adhesive 156 may be in the form of liquid or a tape. A semiconductor device 158 may be placed on the insulation adhesive 156 by the facedown method. In other words, solder bumps 160 that act as conduction and bonding members are pre-installed on electrodes of the semiconductor device 158. The semiconductor device 158 is placed with the solder bumps 160 directed toward the leads 152.

At least one of the semiconductor device 158 and the substrate 150 is pressed against the other with a predetermined pressure. The pressure is preferably more than about 5 Kg/MM². The insulation adhesive 156 is heated at the same time the pressure is applied. Heating is conducted at a temperature (about 50˜200° C.) that melts the insulation adhesive 156 but does not melt the solder bumps 160.

As a result, the solder bumps 160 sink in the insulation adhesive 156 and contact with the leads 152 as shown in FIG. 7(c). Then, the reflow process is performed to heat and melt the solder bumps 160 at a melting point (about 200˜250° C.) to bond to the leads 152. Then, a semiconductor apparatus is obtained as solder bumps (not shown) are provided on the conduction sections 154 to form external electrodes (external terminal).

In accordance with the present embodiment, the position of the semiconductor device 158 is adjusted and placed on the insulation adhesive 156. As a result, the position of the semiconductor device 158 is temporarily retained. Then, the reflow process is performed while the position of the semiconductor device 158 is retained. The insulation adhesive 156 not only temporarily retains the position of the semiconductor device 158, but also finctions as molding resin after the solder bumps 160 are bonded to the leads 152. Therefore, in accordance with the present embodiment, the number of manufacturing steps and thus the manufacturing cost are further reduced compared to methods in which the bonding process is performed earlier than the resin sealing process.

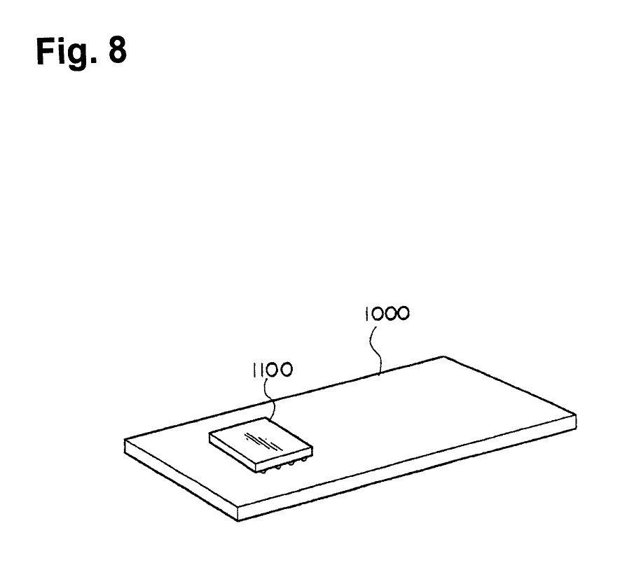

FIG. 8 shows a circuit substrate 1000 having a semiconductor apparatus 1100 in accordance with the present invention mounted thereon. The circuit substrate 1000 is typically formed from an organic substrate such as a glass-epoxy substrate or the like. Wire patterns of copper or the like defining a predetermined circuit are formed on the circuit substrate. The wire patterns and the bumps of the semiconductor apparatus are mechanically connected together to obtain electrical conduction between them.

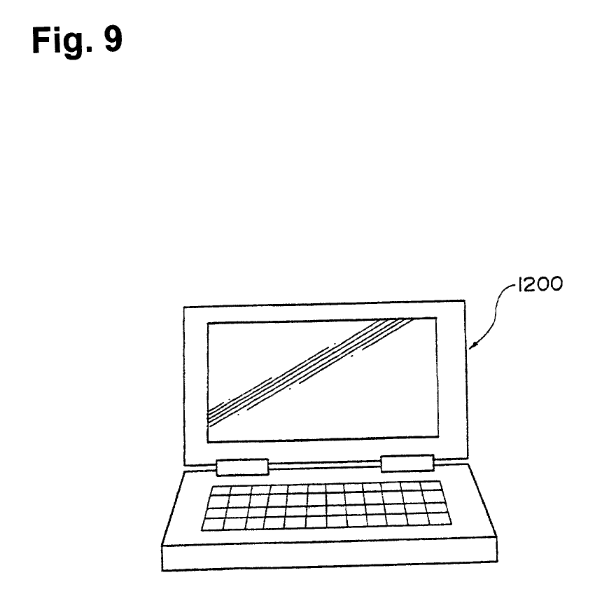

FIG. 9 shows a notebook type personal computer 1200 as an example of an electronic apparatus equipped with the circuit substrate 1000.

The present invention is applicable to manufacturing electronic devices (both active devices and passive devices) for mounting that requires numerous bumps such as semiconductor apparatuses. The electronic devices include, for example, resistors, capacitors, coils, oscillators, filters, temperature sensors, thermistors, varistors, volumes, fuses and the like.

While the invention has been described in relation to preferred embodiments, many modifications and variations are apparent from the description of the invention, and all such modifications and variations are intended to be within the scope of the present invention as defined in the appended claims.

What is claimed is:

1. A semiconductor apparatus comprising:
a substrate main body having a mounting surface for mounting the semiconductor device;
a plurality of leads formed on the mounting surface; and
a plurality of conduction sections each defining at least part of an external terminal, wherein the conduction sections are electrically connected to the leads.

2. The semiconductor apparatus of claim 1, wherein the substrate main body comprises a plurality of through-holes, internal surfaces of the through-holes are conductive and connected to respective leads, and predetermined ones of the internal surfaces define the conduction sections as the substrate main body is cut along corresponding ones of the through-holes.

3. The semiconductor apparatus of claim 1, wherein the substrate main body defines a central area and has one through-hole on the side of the central area for each of the leads, and the conduction sections are formed on a surface opposite of a mounting surface of the semiconductor device and are electrically connected to the leads through the through-holes.

4. The semiconductor apparatus of claim 1, wherein the substrate main body has a plurality of through-holes for each of the leads, and the conduction sections are formed on a surface opposite of the mounting surface of the device and are electrically connected to each corresponding one of the leads through a predetermined one of the through-holes.

5. The semiconductor apparatus of claim 1, wherein the plurality of leads radially extend from a peripheral area toward the central area of the substrate main body.

6. An electronic apparatus having a circuit substrate mounted with the semiconductor apparatus according to claim 1.

7. A semiconductor apparatus comprising:
a semiconductor device having a plurality of electrodes;
a substrate main body;
a plurality of leads formed on the substrate main body; and
a plurality of conduction sections formed on the substrate main body,
wherein the conduction sections are electrically connected to the leads, and one of the conduction sections defines an external terminal.

8. The semiconductor apparatus of claim 7, wherein the substrate main body comprises a plurality of through-holes, internal surfaces of the through-holes are conductive and connected to respective leads, and predetermined ones of the internal surfaces define the conduction sections as the substrate main body is cut along corresponding ones of the through-holes.

9. The semiconductor apparatus of claim 7, wherein the substrate main body defines a central area and has one through-hole on the side of the central area for each of the leads, and the conduction sections are formed on a surface opposite of a mounting surface of the semiconductor device and are electrically connected the leads through the through-holes.

10. The semiconductor apparatus of claim 7, wherein the substrate main body has a plurality of through-holes for each of the leads, and the conduction sections are formed on a surface opposite of the mounting surface of the device and are electrically connected to each corresponding one of the leads through a predetermined one of the through-holes.

11. The semiconductor apparatus of claim 7, wherein the plurality of leads radially extend from a peripheral area toward the central area of the substrate main body.

12. An electronic apparatus having a circuit substrate mounted with the semiconductor apparatus according to claim 7.

13. A method of manufacturing a semiconductor apparatus, comprising:
a step of preparing a substrate including a plurality of leads and a plurality of conduction sections defining at least a part of external terminals, each of the leads being electrically connected to corresponding ones of the conduction sections;
a step of mounting a semiconductor device on the substrate;
a step of electrically connecting electrodes of the semiconductor device to the leads; and
a step of cutting the substrate while leaving uncut at least one of the conduction sections connected to a corresponding lead.

14. The method of claim 13, wherein the semiconductor device includes a surface having the electrodes, the surface of the semiconductor device is attached to the substrate, and the electrodes of the semiconductor device are directly connected to the leads.

15. The method of claim 14, further comprising a step of providing conductive connection member at the electrodes of the semiconductor device, wherein the step of electrically connecting the electrodes and the leads includes a step of providing insulation adhesive members between the electrodes and the leads, a step of pushing the semiconductor device against the substrate and heating the semiconductor device and the substrate at a temperature higher than a melting temperature of the insulation adhesive member and lower than a melting temperature of the conductive connection member, and a step of melting the conductive connection member.

16. The method of claim 13, wherein the substrate is provided with a through-hole for each of the leads, the through-holes communicate with leads on the side of a central area of the substrate, and wherein the conduction sections are electrically connected to corresponding ones of the leads through the through-hole of the substrate and the substrate is cut after the step for electrically connecting the electrodes and the leads.

17. The method of claim 13, wherein the substrate is provided with a plurality of through-holes for each of the leads, the through-holes communicate with the leads, the conduction sections are electrically connected to corresponding ones of the leads through predetermined ones of the through-holes, and the substrate is cut after the step for electrically connecting the electrodes and the leads.

18. The method of claim 13, wherein the substrate is provided with a plurality of through-holes for each one of the leads, internal surfaces of the through-holes are made to be conductive and connected to the corresponding one of the leads, and the substrate is cut at locations that pass predetermined ones of the through-holes to define the conduction sections.
